(19) United States
(12) Patent Application Publication
(10) Pub. No.: US 2010/0193940 A1
(43) Pub. Date: Aug. 5, 2010

(54) Wafer level package and method of manufacturing the same

(75) Inventors: Tae Hyun Kim, Seoul (KR); Tae Hoon Kim, Suwon-si (KR); Yun Pyo Kwak, Suwon-si (KR); Sung Keun Park, Suwon-si (KR); Jong Yeol Jeon, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/382,907

(22) Filed: Mar. 26, 2009

(30) Foreign Application Priority Data
Feb. 4, 2009 (KR) 10-2009-0008717

(51) Int. Cl. H01L 23/02; H01L 21/52

(52) U.S. Cl. 257/701; 438/113; 257/E23.18; 257/E21.5

(57) ABSTRACT

The present invention relates to a wafer level package and a method of manufacturing the same. The wafer level package includes a first substrate including a first region and second regions with grooves around the first region; a semiconductor device positioned in the first region; first sealing members positioned in the grooves; a second substrate including projection units corresponding to the second regions in order to form a cavity corresponding to the first region; and second sealing members which are positioned above the projection units and laminate the first and second substrates to each other by being bonded to the first sealing members, and can prevent the sealing members from flowing to any region except for the sealing regions.

### CROSS-REFERENCE TO RELATED APPLICATIONS

This application claims the benefit of Korean Patent Application No. 10-2009-0008717 filed with the Korea Intellectual Property Office on Feb. 4, 2009, the disclosure of which is incorporated herein by reference.

### BACKGROUND OF THE INVENTION

1. Field of the Invention

The present invention relates to a wafer level package and a method of manufacturing the same; and, more particularly, to a wafer level package capable of preventing sealing members from flowing to any region except for sealing regions by forming grooves in the sealing regions and forming the sealing members in the grooves, and a method of manufacturing the same.

2. Description of the Related Art

A recent trend of electronics industry is to manufacture a lightened, miniaturized, high speed, multi-function, and high performance product having high reliability at a low cost. One of important technologies which can achieve an object of designing such a product is the very semiconductor package.

Since the semiconductor package, that is a technology for effectively packaging a device used in an electronic product, decides a performance of a semiconductor device and a price, a performance, and reliability of a final product, the semiconductor package has been developed in various types.

According to a trend of the semiconductor device toward miniaturization, interest in a wafer level package technology among the semiconductor package technologies is growing. Unlike a conventional method of individually packaging chips cut from a wafer, the wafer level package technology finishes assembly on a wafer on which chips are not divided.

A wafer level package includes a first substrate, a semiconductor device mounted on the first substrate, and a second substrate for sealing the semiconductor device by being bonded to the first substrate.

In order to manufacture such a wafer level package, a bonding process should be performed to bond the first substrate and the second substrate to each other.

As for the bonding process, a metallic bonding process has high selectivity of materials used as the first and second substrates. That is, the metallic bonding process can be performed regardless of a kind of the materials of the first and second substrates.

The metallic bonding process includes a diffusion bonding method and a liquid bonding method. The diffusion bonding method has been widely used because it reduces a void occurrence rate and increases interface bonding force.

Meanwhile, since the liquid bonding method performs a bonding process when solder is melted by being heated at above a melting point, the melted solder may flows from a bonding region to other regions, e.g., a semiconductor device to thereby contaminate the semiconductor device. Furthermore, a void may occur as much as the melted solder flows from the bonding region to the other regions when the two substrates are bonded by the solder in the bonding region, which results in reduction of bonding force between the first and second substrates.

### SUMMARY OF THE INVENTION

The present invention has been invented in order to overcome the above-described problems and it is, therefore, an object of the present invention to provide a wafer level package capable of preventing sealing members from flowing to any region except for sealing regions by forming grooves in the sealing regions and forming the sealing members in the grooves, and a method of manufacturing the same.

In accordance with one aspect of the present invention to achieve the object, there is provided a wafer level package including: a first substrate including a first region and second regions with grooves around the first region; a semiconductor device positioned in the first region; first sealing members positioned in the grooves; a second substrate including projection units corresponding to the second regions in order to form a cavity corresponding to the first region; and second sealing members which are positioned above the projection units and laminate the first and second substrates to each other by being bonded to the first sealing members.

Herein, the first sealing members have a first melting point and the second sealing members have a second melting point higher than the first melting point.

Further, the first sealing members are formed of metal or resin.

Further, the second sealing members are formed of metal.

Further, the first substrate is any one selected from a group consisting of an LTCC(Low Temperature Co-fired Ceramic) substrate, an HTCC(High Temperature Co-fired Ceramic) substrate, a PCB(Printed Circuit Board), a silicon substrate, a glass substrate, and a quartz substrate.

Further, the second substrate is any one selected from a group consisting of a glass substrate, a ceramic substrate, a silicon substrate, and a quartz substrate.

Further, the second sealing members are inserted into the first sealing members.

Further, the wafer level package further includes metal layers at lower parts of the first sealing members on inner walls of the grooves.

Further, the wafer level package further includes metal patterns at lower parts of the second sealing members on the second substrate.

Further, the grooves are positioned along edges of the first substrate.

In accordance with another aspect of the present invention to achieve the object, there is provided a method for manufacturing a wafer level package including the steps of: separately preparing a first substrate including first regions in which semiconductor devices are positioned and second regions with grooves around the first regions, and a second substrate facing the first substrate; forming first sealing members in the grooves of the first substrate; forming second sealing members above the second substrate corresponding to the second regions; forming cavities corresponding to the first regions by forming projection units corresponding to the second regions; and laminating the first substrate and the second substrate by bonding the first sealing members and the second sealing members in order to seal the semiconductor devices.

Herein, the method further includes a step of forming metal layers in the grooves before the step of forming the first sealing members.

Further, the first sealing members have a first melting point and the second sealing members have a second melting point higher than the first melting point.

Further, the first substrate is any one selected from a group consisting of an LTCC(Low Temperature Co-fired Ceramic) substrate, an HTCC(High Temperature Co-fired Ceramic) substrate, a PCB(Printed Circuit Board), a silicon substrate, a glass substrate, and a quartz substrate.

Further, the second substrate is any one selected from a group consisting of a glass substrate, a ceramic substrate, a silicon substrate, and a quartz substrate.

Further, the step of forming the second sealing members includes the steps of: forming a seed layer on the second substrate; forming first resist patterns on the seed layer; forming second sealing members on the seed layer corresponding to exposed regions of the first resist patterns; forming second resist patterns covering the second sealing members; and forming metal patterns by etching the seed layer by using the second resist patterns as an etching mask.

Further, the step of forming the second sealing members includes the steps of: forming a seed layer on the second substrate; forming resist patterns on the seed layer; forming metal patterns by etching the seed layer by using the resist patterns as an etching mask; and forming the second sealing members on the metal patterns.

Further, the method further includes a step of: dicing the laminated first and second substrates into individual units.

Further, a dicing process is performed along dicing lines positioned inside the second regions.

In accordance with still another aspect of the present invention to achieve the object, there is provided a wafer level package including: a first substrate including a first region and second regions positioned around the first region; a semiconductor device positioned in the first region; first sealing members positioned in the second regions; a second substrate including projection units corresponding to the second regions in order to form a cavity corresponding to the first region; grooves positioned on the projection units; and second sealing members which are positioned in the grooves and laminate the first and second substrates by being bonded to the first sealing members.

Herein, the first sealing members are formed of metal patterns.

Further, the wafer level package further includes metal layers positioned inside the grooves.

Further, the second sealing members are formed of metal or resin.

Further, the first sealing members have a melting point higher than the second sealing members.

In accordance with still another aspect of the present invention to achieve the object, there is provided a wafer level package including: first and second substrates facing each other; a semiconductor device positioned on the first substrate; and sealing members for laminating the first and second substrates to seal the semiconductor device.

Any one of the first and second substrates includes grooves filled with the sealing members.

Herein, the grooves are formed on the first substrate and the second substrate includes projection units corresponding to the grooves.

Herein, the second substrate includes the projection units corresponding to the sealing members and the grooves are formed on the projection units.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view illustrating a wafer level package in accordance with a first embodiment of the present invention;

FIGS. 2 to 12 are cross-sectional views illustrating a method of manufacturing a wafer level package in accordance with a second embodiment of the present invention;

FIGS. 13 to 18 are cross-sectional views illustrating a method of manufacturing a wafer level package in accordance with a third embodiment of the present invention;

FIG. 19 is a cross-sectional view illustrating a wafer level package in accordance with a fourth embodiment of the present invention; and

FIG. 20 is a cross-sectional view illustrating a wafer level package in accordance with a fifth embodiment of the present invention.

### DETAILED DESCRIPTION OF THE PREFERABLE EMBODIMENTS

Hereinafter, embodiments of the present invention for a wafer level package will be described in detail with reference to the accompanying drawings. The following embodiments are provided as examples to fully convey the spirit of the invention to those skilled in the art. Therefore, the present invention should not be construed as limited to the embodiments set forth herein and may be embodied in different forms and. And, the size and the thickness of an apparatus may be overdrawn in the drawings for the convenience of explanation. The same components are represented by the same reference numerals hereinafter.

FIG. 1 is a cross-sectional view illustrating a wafer level package in accordance with a first embodiment of the present invention.

Referring to FIG. 1, in accordance with the embodiment of the present invention, the wafer level package includes first and second substrates 110 and 120 which face each other, a semiconductor device positioned on the first substrate 110, and sealing members 130 and 140 for laminating the first and second substrates 110 and 120 to each other in order to seal the semiconductor device 115.

The first substrate 110 may include a first region 110a and second regions 110b.

Herein, the semiconductor device 115 is positioned in the first region 110a. Internal pads 111 which are electrically connected to the semiconductor device 115 may be formed in the first region 110a. External pads 112 may be positioned on an external surface of the first substrate 110 to be electrically connected to an external device. At this time, the internal pads 111 and the external pads 112 may be electrically connected to each other by vias 113 that penetrate the first substrate 110.

Although not shown in the drawing, a plurality of circuit patterns may be further formed in the first region 110a of the first substrate 110.

Further, the second regions 110b are positioned around the first region 110a.

At this time, grooves 114 are formed in the second regions 110b. In other words, the grooves 114 are formed along edges of the first substrate 110. As a result, the second regions 110b have small steps compared with the first region 110a.

Since the following sealing members 130 and 140 can bond various substrates to each other, they have high selectivity of a material of the first substrate 110. Therefore, the first substrate 110 can be selected from various materials. For example, the first substrate 110 may be formed of any one of an LTCC(Low Temperature Co-fired Ceramic) substrate, an HTCC(High Temperature Co-fired Ceramic) substrate, a PCB(Printed Circuit Board), a silicon substrate, a glass substrate, and a quartz substrate.

Meanwhile, the second substrate 120 includes projection units 121 which correspond to the second regions 110b. Therefore, the second substrate 120 includes a cavity 122 which corresponds to the first region 110a. That is, the second regions 110b have large steps compared with the first region 110a.

The second substrate 120 may be made of a material which can protect the semiconductor device 115. Further, like the first substrate 110, the second substrate 120 has high selectivity of a material because the following sealing members 130 and 140 can bond various substrates to each other, and thus the second substrate 120 can use various kinds of materials. For instance, the second substrate 120 may be formed of any one of a glass substrate, a ceramic substrate, a silicon substrate, and a quartz substrate.

The sealing members 130 and 140 may include first and second sealing members 130 and 140 which are formed on the first and second substrates 110 and 120, respectively.

Herein, the first sealing members 130 are formed in the grooves 114. Therefore, in case that the first and second substrates 110 and 120 are laminated through the sealing members 130 and 140, the grooves 114 can prevent the first sealing members 130 from flowing to any regions except for sealing regions. In addition, the first sealing members 130 have a first melting point. For example, the first melting point may be in the range of 50-600° C. Herein, the first sealing members 130 may be made of a metal such as In, Bi, Sn, SnAg, SnCu, and SnAgCu or a resin such as an epoxy resin.

Meanwhile, the second sealing members 140 may be positioned above the second substrate 120 which corresponds to the second regions 110b. That is, the second sealing members 140 may be positioned above the projection units 121. Further, the second sealing members 140 may have a second melting point higher than the first melting point. For example, the second melting point may be in the range of 100-1,500° C. Herein, the second sealing members 140 may be made of a metal such as Cu, Al, Bi, Au, Ni, Ag, Sn, In, and Pb.

When the first and second sealing members 130 and 140 are bonded to each other, the first and second substrates 110 and 120 are laminated while facing each other. At this time, the semiconductor device 115 is sealed from the outside by the first and second substrates 110 and 120 and the sealing members 130 and 140. At this time, the second sealing members 140 have widths smaller than the grooves 114. Therefore, the second sealing members 140 are inserted into the grooves 114 and thus the first and second sealing members 130 and 140 are bonded to each other while the second sealing members 140 are inserted into the first sealing members 130 which are filled in the grooves. In other words, the first and second sealing members can achieve the three-dimensional interface bonding, not the two-dimensional interface bonding, thereby improving breaking strength between the first and second substrates 110 and 120 and airtightly sealing the semiconductor device 115.

In addition, metal layers 150 are further provided at lower parts of the first sealing members 130 on inner walls of the grooves 114. The metal layers 150 can play a role of enhancing contact stability between the first sealing members 130 and the first substrate 110. As for a material of the metal layer 150, Cu, Ti, Ni, TiW, Au, and so on may be exemplified.

Further, metal patterns 160 may be further provided between the second sealing members 140 and the second substrate 120. The metal patterns 160 can play a role of enhancing contact stability between the second sealing members 140 and the second substrate 120. As for a material of the metal pattern 160, Cu, Ti, Ni, TiW, Au, and so on may be exemplified. Further, the metal patterns 160 can play a role of seeds for forming the second sealing members 140.

Therefore, in accordance with the embodiment of the present invention, since after forming the grooves in the second regions, i.e., the sealing regions, the sealing members are formed in the grooves, it is possible to prevent the sealing members from flowing to any regions except for the sealing regions, thereby preventing the semiconductor device from being contaminated and improving bonding force between the two substrates.

Further, it is possible to increase the breaking strength and improve an airtight sealing characteristic in comparison with the related art through the three-dimensional interface bonding.

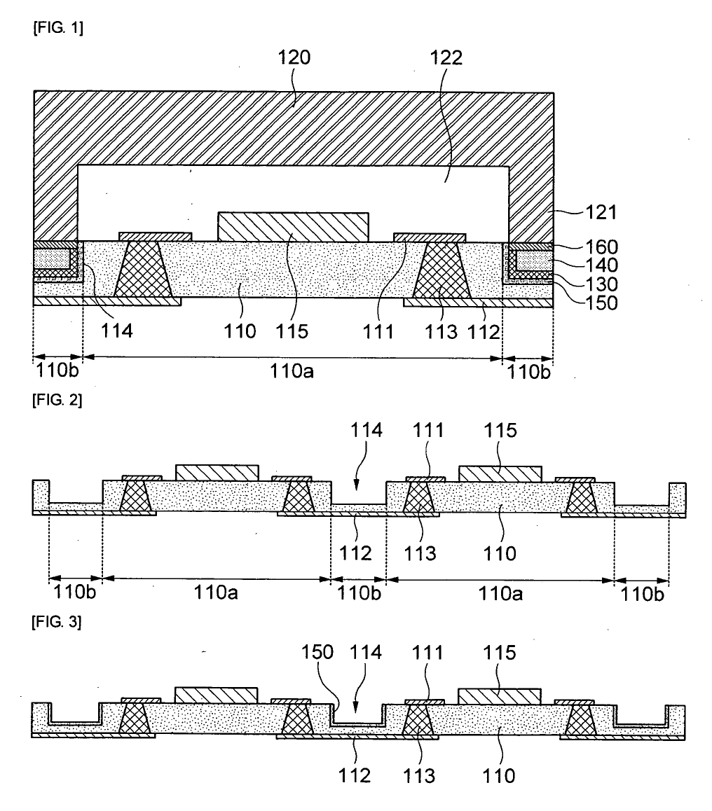

Hereinafter, a method of manufacturing a wafer level package in accordance with a second embodiment of the present invention will be described with reference to FIGS. 2 to 12.

FIGS. 2 to 12 are cross-sectional views illustrating a method of manufacturing a wafer level package in accordance with a second embodiment of the present invention.

Referring to FIG. 2, in order to manufacture the wafer level package, first of all, first and second substrates 110 and 120 are separately prepared.

At first, the first substrate 110 includes first regions 110a and second regions 110b. Herein, semiconductor devices 115 may be mounted in the first regions 110a. In addition, internal pads 111 may be further provided on the first substrate 110 which corresponds to the first regions 110a. External pads 112 may be provided on a bottom surface of the first substrate 110. At this time, the internal pads 111 and the external pads 112 are electrically connected to each other by vias 113 which penetrate the first substrate 110.

The second regions 110b are positioned around the first regions 110a. At this time, grooves 114 are formed in the second regions 110b.

The grooves 114 may be formed through an etching method or a scribing method. Herein, as examples of the etching method, there is a wet etching method or a dry etching method. Further, as examples of the scribing method, blade sawing or a laser may be used.

The first substrate 110 may be any one selected from an LTCC(Low Temperature Co-fired Ceramic) substrate, an HTCC(High Temperature Co-fired Ceramic) substrate, a PCB(Printed Circuit Board), a silicon substrate, a glass substrate, and a quartz substrate.

Referring to FIG. 3, metal layers 150 are formed inside the grooves 114. The metal layers 150 may be formed through a deposition method using a mask or through patterning after depositing a metal. As examples of a material of the metal layer 150, there are Cu, Ti, Ni, TiW, Au, and so on.

Referring to FIG. 4, first sealing members 130 are formed on the metal layers 150 inside the grooves 114. The first sealing members 130 may be made of a material having a first melting point. For example, the first melting point may be in the range of 50-600° C. Herein, the first sealing members 130 may be a metal such as In, Bi, Sn, SnAg, SnCu, and SnAgCu or a resin such as an epoxy resin.

The first sealing members 130 may be formed through various methods. For example, the various methods of forming the first sealing member 130 includes vapor deposition, plating, screen printing, dispensing, and so on.

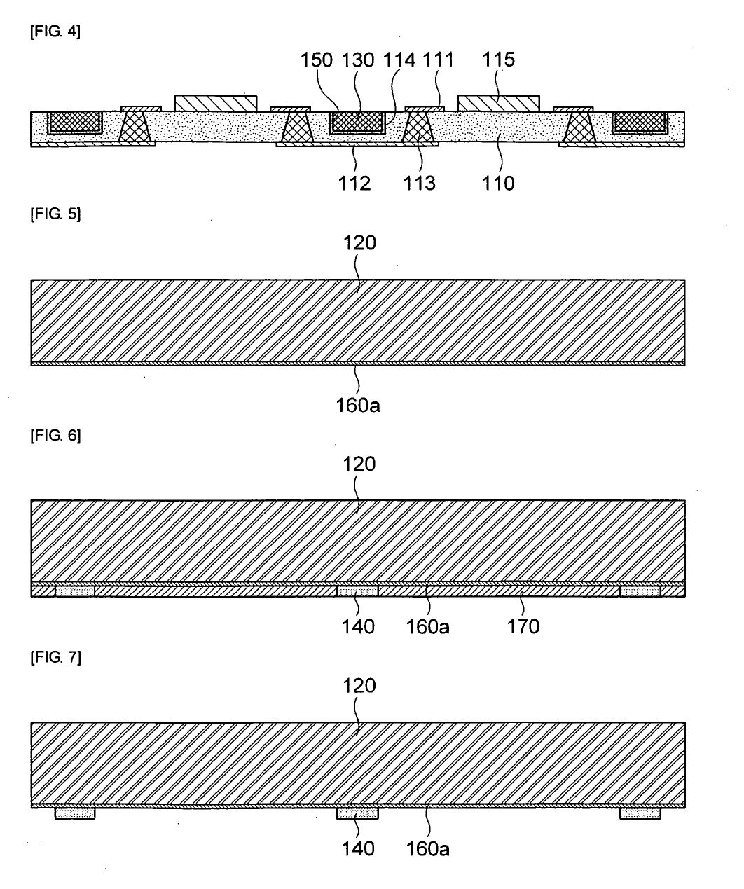

Meanwhile, referring to FIG. 5, a seed layer 160a is formed on a second substrate 120. The second substrate 120 may be any one of a glass substrate, a ceramic substrate, a silicon substrate, and a quartz substrate.

The seed layer 160a may be formed through deposition. The seed layer 160a may be formed of Cu, Ti, Ni, TiW, Au, or the like.

Referring to FIG. 6, first resist patterns 170 are formed on the seed layer 160a. Herein, the first resist patterns 170 are formed to expose regions corresponding to the second regions 110b of the first substrate 110.

The first resist patterns 170 may be formed through exposing and developing processes or a printing method.

Thereafter, second sealing members 140 are formed on the seed layer 160a corresponding to exposed regions of the first resist patterns 170. The second sealing members 140 may be formed through a plating process using the seed layer 160a. Herein, the second sealing members 140 may have a second melting point higher than the first melting point. For example, the second melting point may be in the range of 100-1,500° C. Herein, the second sealing members 140 may be a metal such as Cu, Al, Bi, Au, Ni, Ag, Sn, In, and Pb.

Although in the embodiment of the present invention, the second sealing members 140 have been explained for a case that they are formed through the plating process, they may be formed through a deposition process without being limited to this embodiment.

Referring to FIG. 7, the first resist patterns 170 are removed.

Referring to FIG. 8, metal patterns 160 are formed by etching the seed layer 160a. Specifically, although not shown in the drawing, second resist patterns are formed, which cover the second sealing members 140 and expose regions corresponding to the first regions 110a of the first substrate 110. The metal patterns 160 may be formed by etching the seed layer 160a by using the second resist patterns as an etching mask. Herein, the metal patterns 160 are formed to have widths smaller than the grooves.

Thereafter, a process of removing the second resist patterns is performed.

In case that the second sealing members 140 are formed through the plating process, the metal patterns 160 play a role of seeds. Further, the metal patterns 160 can play a role of improving contact stability between the second sealing members 140 and the second substrate 120.

Further, the metal patterns 160 are formed to have widths smaller than the grooves 114.

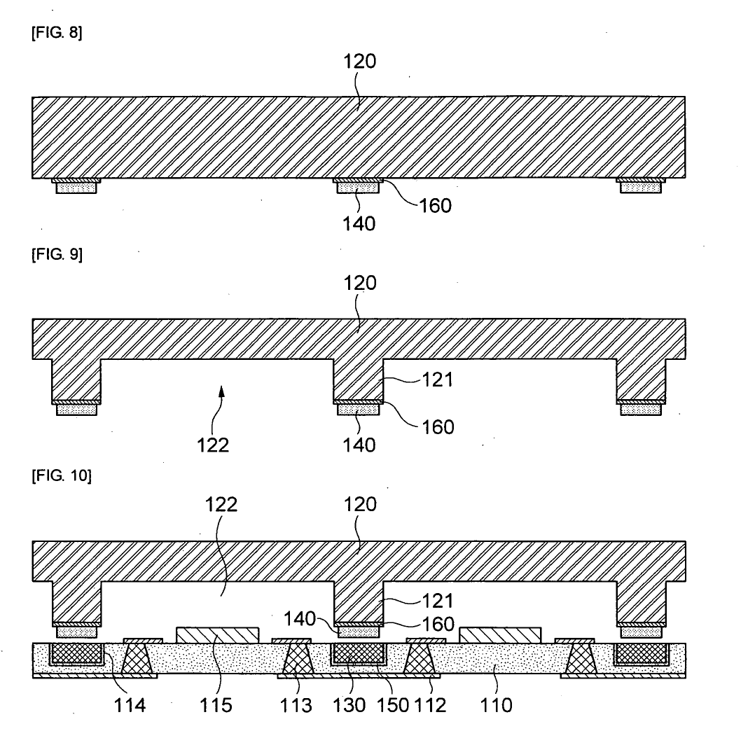

Referring to FIG. 9, a portion of the second substrate 120 corresponding to the first regions 110a is etched. Therefore, projection units 121 are formed on the second substrate 120 corresponding to the second regions 110b and so the second substrate 120 includes cavities 122 which are positioned to correspond to the first regions 110a.

Referring to FIG. 10, the first substrate 110 including the first sealing members 130 and the second substrate 120 including the second sealing members 140 are aligned to face each other. At this time, the semiconductor devices 115 are located inside the cavities 122.

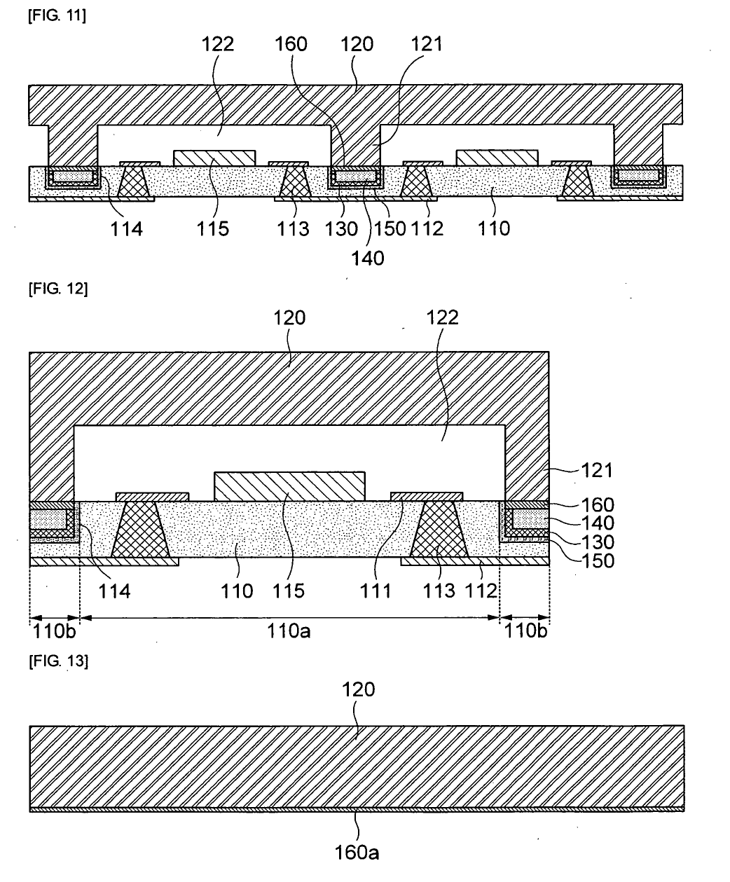

Referring to FIG. 11, the aligned first and second substrates 110 and 120 are heated at a temperature at which the first sealing members 130 can be melted but the second sealing members 140 can not be melted. At this time, the second sealing members 140 can be inserted into the melted first sealing members 130 inside the grooves 114.

Herein, as the melted first sealing members 130 are wet to the second sealing member 140, bonding between the first and second sealing members 130 and 140 is achieved through metallic bonding between the first and second sealing members 130 and 140. That is, the second sealing members 140 are not melted in a bonding process and the shape thereof is maintained. On the other hand, the first sealing members 130 are melted to achieve the metallic bonding through an interface reaction in which it reacts to the second sealing members 140. Therefore, the second sealing members 140 can be bonded to the first sealing members 130 three-dimensionally, thereby increasing breaking strength between the first and second substrates 110 and 120 and further enhancing an airtight sealing characteristic.

Further, since the first and second sealing members 130 and 140 are bonded to each other by melting the first sealing members 130, additional pressure does not need to be applied.

Further, a heating temperature can be controlled according to a kind of the first sealing members 130.

Further, since the first sealing members 130 are provided in the grooves 114 in the bonding process, it is possible to prevent the first sealing members 130 from flowing to any regions except for sealing regions.

Referring to FIG. 12, a process of dividing the laminated substrates into individual units is performed by dicing them along the projection units 121, i.e., dicing lines positioned inside the second regions 110b. At this time, a dicing process may be performed through a blade method, a laser method, or the like.

Therefore, in accordance with the embodiment of the present invention, it is possible to prevent the sealing members from flowing to any regions except for the sealing regions by forming the sealing members in the grooves after forming the grooves in the sealing regions, thereby preventing the semiconductor device from being contaminated and improving the bonding force between the two substrates.

Further, since the bonding process is performed by forming the sealing members having different melting points on the first and second substrates, respectively, and melting the sealing members having the lower melting point through heating, the bonding process can be performed without the need for high pressure, thereby facilitating the process and reducing equipment investment costs.

Further, it is possible to freely select a temperature of the bonding process depending on a kind of the sealing members.

Further, it is possible to increase breaking strength and improve an airtight sealing characteristic through three-dimensional bonding as compared with the related art.

FIGS. 13 to 18 are cross-sectional views illustrating a method of manufacturing a wafer level package in accordance with a third embodiment of the present invention. The method of the third embodiment of the present invention is the same as that of the second embodiment as described above except for a step of forming metal patterns. Therefore, in the third embodiment of the present invention, overlapping description with the second embodiment will not be repeated and the same components are represented by the same reference numerals.

The method of manufacturing the wafer level package in accordance with the third embodiment of the present invention will be described with reference to FIGS. 13 to 18.

Referring to FIG. 13, in order to manufacture the wafer level package, a seed layer 160a is formed on the second substrate 120. The seed layer 160a may be formed through deposition. The seed layer 160a may be formed of Cu, Ti, Ni, TiW, Au, and so on.

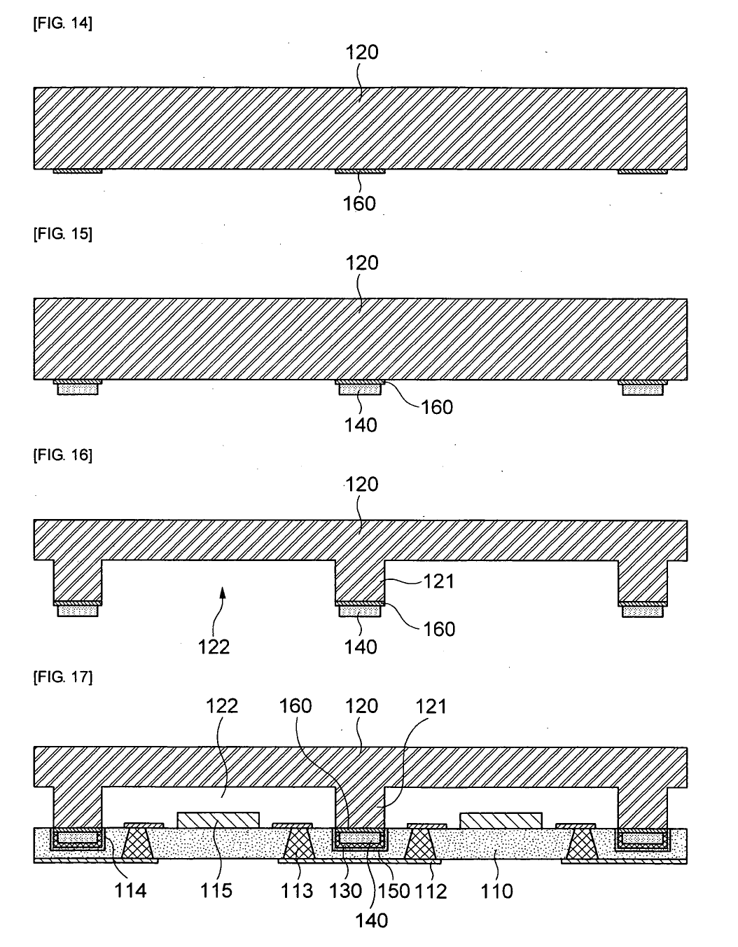

Referring to FIG. 14, metal patterns 160 are formed by etching the seed layer 160a. Herein, the metal patterns 160 may be formed to correspond to second regions 110b of the following first substrate 110. Specifically, in order to form the metal patterns 160, at first, resist patterns are formed on the seed layer 160a. Thereafter, the seed layer 160a is etched by using the resist patterns as an etching mask in order to form the metal patterns 160.

Referring to FIG. 15, second sealing members 140 are formed on the metal patterns 160 through a plating process using the metal patterns 160 as seeds. Herein, the second sealing members 140 may have a second melting point higher than a first melting point. For example, the second melting point may be in the range of 100-1,500° C. Herein, the second sealing members 140 may be a metal such as Cu, Al, Bi, Au, Ni, Ag, Sn, In, and Pb. Although in the embodiment of the present invention, the second sealing members 140 have been explained for a case that they are formed through the plating process, they may be formed through a deposition process without being limited to this embodiment.

Referring to FIG. 16, projection units 121 are formed on the second substrate 120 corresponding to the second regions 110b by etching a portion of the second substrate 120 corresponding to first regions 110a of the first substrate 110. Therefore, the second substrate 120 includes cavities 122 which are positioned to correspond to the first regions 110a.

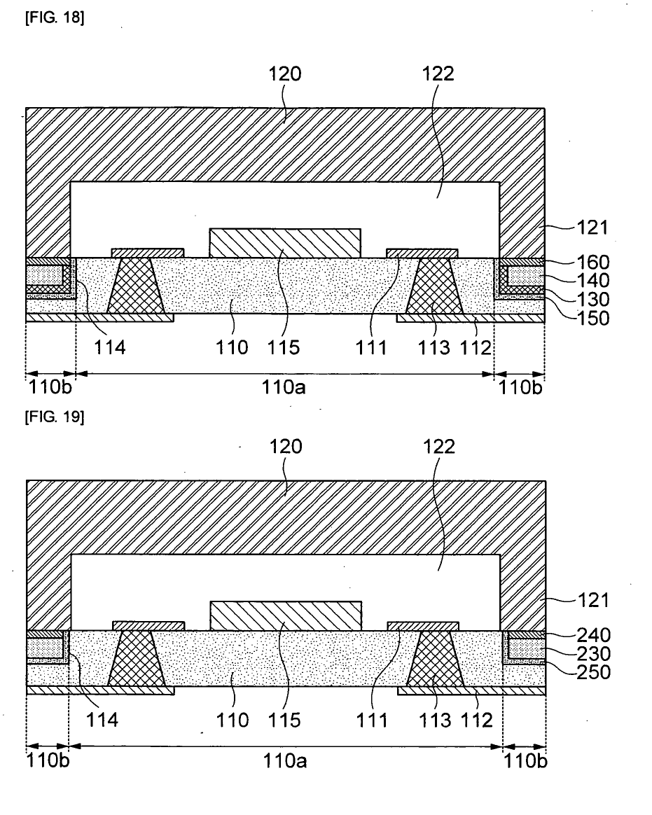

Referring to FIG. 17, the second substrate 120 is aligned on the first substrate 110 including the first regions 110a and the second regions 110b to face the first substrate 110. Herein, semiconductor devices 115 are mounted in the first regions 110a of the first substrate 110. Further, grooves 114 are formed in the second regions 110b and first sealing members 130 are formed in the grooves 114. Herein, the first sealing members 130 may be made of a metal or a resin having a melting point lower than the second sealing members 140.

Thereafter, the aligned first and second substrates 110 and 120 are heated. As a result, a bonding reaction is achieved between the first and second sealing members 130 and 140 and so the first and second substrates 110 and 120 are laminated to each other while sealing the semiconductor devices.

Referring to FIG. 18, a process of dividing the laminated substrates into individual units is performing by dicing them along dicing lines positioned inside the second regions 110b.

Therefore, in accordance with the embodiment of the present invention, since after forming the metal patterns, the second sealing members are formed by using the metal patterns, the process can be all the more simplified.

Hereinafter, a wafer level package in accordance with a fourth embodiment of the present invention will be described with reference to FIG. 19. Because the wafer level package of the fourth embodiment of the present invention have the same components as those of the wafer level package in accordance with the first embodiment except for the second sealing members of the first embodiment, overlapping description will not be repeated.

FIG. 19 is a cross-sectional view illustrating a wafer level package in accordance with a fourth embodiment of the present invention.

Referring to FIG. 19, in accordance with the embodiment of the present invention, the wafer level package includes first and second substrates 110 and 120 which face each other, a semiconductor device 115 positioned on the first substrate 110, and sealing members 230 and 240 for laminating the first and second substrates 110 and 120 in order to seal the semiconductor device 115.

Herein, the first substrate 110 includes a first region 110a and second regions 110b, in which grooves 114 are formed, around the first region 110a.

Further, the second substrate 120 includes projection units 121 corresponding to the second regions 110b in order to form a cavity 122 corresponding to the first region 110a.

The sealing members 230 and 240 includes first and second sealing members 230 and 240 which laminate the first substrate 110 and the second substrate 120 by being bonded to each other.

The first sealing members 230 are positioned in the grooves 114. The first sealing members 230 may be made of a resin or a metal having a melting point lower than that of the second sealing members 240. Herein, the second sealing members 240 may be formed of single film of metals. At this time, the first sealing members 230 are bonded to the second sealing members 240 through a liquid reaction in a melted state. At this time, as the first and second sealing members 230 and 240 are bonded, the first and second substrates 110 and 120 can be laminated to seal the semiconductor device 115.

In addition, metal layers 250 are further provided on inner walls of the grooves 114 of the first substrate 110, i.e., between the first substrate 110 and the first sealing members 230.

Therefore, in accordance with the embodiment of the present invention, since the second sealing members are formed of the single film of metals, the process can be all the more simplified.

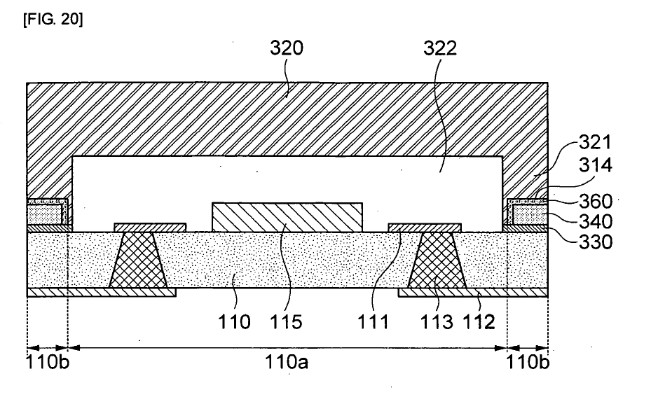

Hereinafter, a wafer level package in accordance with a fifth embodiment of the present invention will be described with reference to FIG. 20. Because in the fifth embodiment of the present invention, the wafer level package have the same components as those of the wafer level package in accordance with the fourth embodiment except for positions of the grooves and the firs and second sealing members in the fourth embodiment, overlapping description will not be repeated.

FIG. 20 is a cross-sectional view illustrating a wafer level package in accordance with a fifth embodiment of the present invention.

Referring to FIG. 20, in accordance with the embodiment of the present invention, the wafer level package includes first and second substrates 110 and 320 which face each other, a semiconductor device 115 positioned on the first substrate 110, and sealing members 330 and 340 for laminating the first and second substrates 110 and 320 to each other in order to seal the semiconductor device 115.

Herein, the first substrate 110 includes a first region 110a and second regions 110b which are positioned around the first region 110a.

Further, the second substrate 120 includes projection units 321 corresponding to the second regions 110b in order to form a cavity 322 corresponding to the first region 110a. At this time, grooves 314 are provided along the projection units 321.

The sealing members 330 and 340 include first and second sealing members 330 and 340. Herein, the first sealing members 330 are positioned on the first substrate 110 in the second regions 110b. At this time, the first sealing members 330 may be formed of single film of metals.

On the other hand, the second sealing members 340 are positioned in the grooves 314. At this time, the second sealing members 340 may be made of a metal or a resin having a melting point lower than that of the first sealing members 330. At this time, the second sealing members 340 are bonded to the first sealing members 330 through a liquid reaction in a melted state. At this time, the first and second substrates 110 and 320 can be laminated while sealing the semiconductor device 115 through bonding between the first and second sealing members 330 and 340.

In addition, metal layers 360 are further provided on inner walls of the grooves 314, i.e., between the second substrate 110 and the second sealing members 340. The metal layers 360 play a role of enhancing contact stability between the second substrate 320 and the second sealing members 340.

Therefore, in accordance with the embodiment of the present invention, the grooves for preventing the sealing members from flowing to any regions except for the sealing regions may be formed on the second substrate.

As described above, the wafer level package of the present invention can prevent the sealing members from flowing to any regions except for the sealing regions by forming the grooves in the sealing regions and forming the sealing members in the grooves, thereby preventing devices including the semiconductor device from being contaminated and improving the bonding force between the two substrates.

Further, the wafer level package of the present invention does not need the high pressure and can freely select the temperature of the bonding process according to the kind of the sealing members.

Further, the wafer level package of the present invention can increase the breaking strength and enhance the airtight sealing characteristic as compared with the related art.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

1. A wafer level package comprising:
a first substrate including a first region and second regions with grooves around the first region;
a semiconductor device positioned in the first region;
first sealing members positioned in the grooves;
a second substrate including projection units corresponding to the second regions in order to form a cavity corresponding to the first region; and
second sealing members which are positioned above the projection units and laminate the first and second substrates to each other by being bonded to the first sealing members.

2. The wafer level package of claim 1, wherein the first sealing members have a first melting point and the second sealing members have a second melting point higher than the first melting point.

3. The wafer level package of claim 1, wherein the first sealing members are formed of metal or resin.

4. The wafer level package of claim 1, wherein the second sealing members are formed of metal.

5. The wafer level package of claim 1, wherein the first substrate is any one selected from a group consisting of an LTCC(Low Temperature Co-fired Ceramic) substrate, an HTCC(High Temperature Co-fired Ceramic) substrate, a PCB(Printed Circuit Board), a silicon substrate, a glass substrate, and a quartz substrate.

6. The wafer level package of claim 1, wherein the second substrate is any one selected from a group consisting of a glass substrate, a ceramic substrate, a silicon substrate, and a quartz substrate.

7. The wafer level package of claim 1, wherein the second sealing members are inserted into the first sealing members.

8. The wafer level package of claim 1, further comprising:
metal layers at lower parts of the first sealing members on inner walls of the grooves.

9. The wafer level package of claim 1, further comprising:
metal patterns at lower parts of the second sealing members on the second substrate.

10. The wafer level package of claim 1, wherein the grooves are positioned along edges of the first substrate.

11. A method for manufacturing a wafer level package comprising:
separately preparing a first substrate including first regions in which semiconductor devices are positioned and second regions with grooves around the first regions, and a second substrate facing the first substrate;
forming first sealing members in the grooves of the first substrate;
forming second sealing members above the second substrate corresponding to the second regions;
forming cavities corresponding to the first regions by forming projection units corresponding to the second regions; and
laminating the first substrate and the second substrate by bonding the first sealing members and the second sealing members in order to seal the semiconductor devices.

12. The method of claim 11, further comprising:
forming metal layers in the grooves before the forming the first sealing members.

13. The method of claim 11, wherein the first sealing members have a first melting point and the second sealing members have a second melting point higher than the first melting point.

14. The method of claim 11, wherein the first substrate is any one selected from a group consisting of an LTCC(Low Temperature Co-fired Ceramic) substrate, an HTCC(High Temperature Co-fired Ceramic) substrate, a PCB(Printed Circuit Board), a silicon substrate, a glass substrate, and a quartz substrate.

15. The method of claim 11, wherein the second substrate is any one selected from a group consisting of a glass substrate, a ceramic substrate, a silicon substrate, and a quartz substrate.

16. The method of claim 11, wherein forming the second sealing members includes:
forming a seed layer on the second substrate;
forming first resist patterns on the seed layer;
forming second sealing members on the seed layer corresponding to exposed regions of the first resist patterns;
forming second resist patterns covering the second sealing members; and
forming metal patterns by etching the seed layer by using the second resist patterns as an etching mask.

17. The method of claim 11, wherein forming the second sealing members includes:
forming a seed layer on the second substrate;
forming resist patterns on the seed layer;
forming metal patterns by etching the seed layer by using the resist patterns as an etching mask; and
forming the second sealing members on the metal patterns.

18. The method of claim 11, further comprising:
dicing the laminated first and second substrates into individual units.

19. The method of claim 18, wherein a dicing process is performed along dicing lines positioned inside the second regions.

20. A wafer level package comprising:
a first substrate including a first region and second regions positioned around the first region;
a semiconductor device positioned in the first region;
first sealing members positioned in the second regions;
a second substrate including projection units corresponding to the second regions in order to form a cavity corresponding to the first region;
grooves positioned on the projection units; and
second sealing members which are positioned in the grooves and laminate the first and second substrates by being bonded to the first sealing members.

21. The wafer level package of claim 20, wherein the first sealing members are formed of metal patterns.

22. The wafer level package of claim 20, further comprising:
metal layers positioned inside the grooves.

23. The wafer level package of claim 20, wherein the second sealing members are formed of metal or resin.

24. The wafer level package of claim 20, wherein the first sealing members have a melting point higher than the second sealing members.

25. A wafer level package comprising:
first and second substrates facing each other;
a semiconductor device positioned on the first substrate; and
sealing members for laminating the first and second substrates to seal the semiconductor device,
wherein any one of the first and second substrates includes grooves filled with the sealing members

26. The wafer level package of claim 25, wherein the grooves are formed on the first substrate and the second substrate includes projection units corresponding to the grooves.

27. The wafer level package of claim 25, wherein the second substrate includes the projection units corresponding to the sealing members and the grooves are formed on the projection units.
